(19) United States
(12) Patent Application Publication
(10) Pub. No.: US 2018/0174623 A1
(43) Pub. Date: Jun. 21, 2018

(54) APPARATUS AND METHOD FOR TRANSFERRING DATA BETWEEN DIFFERENT VOLTAGE-CLOCK DOMAINS USING MULTIPLE WRITE-SIDE MULTIPLEXERS

(71) Applicant: QUALCOMM Incorporated, San Diego, CA (US)

(72) Inventors: Fei Xu, San Jose, CA (US); Rakesh Vattikonda, San Diego, CA (US); Dina McKinney, Los Gatos, CA (US); Zhen Chen, Saratoga, CA (US); Yun Li, San Diego, CA (US); Zhenbiao Ma, Fremont, CA (US); De Lu, San Diego, CA (US)

(21) Appl. No.: 15/381,587

(22) Filed: Dec. 16, 2016

(51) Int. Cl. G11C 7/10; G06F 3/06

(52) U.S. Cl. CPC G11C 7/1012; G06F 3/0604; G06F 3/0683; G06F 3/0647; G06F 3/064

(57) ABSTRACT

An apparatus and method are disclosed for transferring data from a first core to a second core of an integrated circuit (IC). The first core includes first and second memory blocks (e.g., first and second portions of a first-in-first-out (FIFO) memory coupled to first and second pre-multiplexers, respectively). The second core includes a multiplexer including first and second inputs coupled to the first and second memory blocks, respectively. Additionally, the second core includes a read controller configured to generate a first read control signal to cause the first and second memory blocks to transfer data to the first and second inputs of the multiplexer, respectively; and generate a second read control signal to cause the multiplexer to transfer data from the first and inputs to an output of the multiplexer.

### BACKGROUND

### Field

Aspects of the present disclosure relate generally to transferring data between different voltage-clock domains, and in particular, to an apparatus and method for transferring data between different voltage-clock domains using multiple write-side multiplexers.

### Background

An integrated circuit (IC), such as a Silicon on Chip (SOC) type IC, may include a set of distinct cores. The cores may operate under different voltage domains and clock domains. Often, these cores send data to each other. Because the cores operate under different voltage and clock domains, a digital interface circuit is often provided to convert data from a first voltage-clock domain to a second voltage-clock domain when the data is transferred from a first core to a second core.

### SUMMARY

The following presents a simplified summary of one or more embodiments in order to provide a basic understanding of such embodiments. This summary is not an extensive overview of all contemplated embodiments, and is intended to neither identify key or critical elements of all embodiments nor delineate the scope of any or all embodiments. Its sole purpose is to present some concepts of one or more embodiments in a simplified form as a prelude to the more detailed description that is presented later.

An aspect of the disclosure relates to an apparatus including a first core having a first memory block and a second memory block. The apparatus further includes a second core including a multiplexer including first and second inputs coupled to the first and second memory blocks, respectively; and a read controller configured to generate a first read control signal to cause the first and second memory blocks to transfer data to the first and second inputs of the multiplexer, respectively, and generate a second read control signal to cause the multiplexer to transfer data from the first and second inputs to an output of the multiplexer.

Another aspect of the disclosure relates to a method including activating first and second memory blocks within a first core to transfer data to first and second inputs of a multiplexer within a second core, respectively; and activating the multiplexer to transfer data from the first and second inputs to an output of the multiplexer.

Another aspect of the disclosure relates to an apparatus including means for activating first and second memory blocks within a first core to transfer data to first and second inputs of a multiplexer within a second core, respectively; and means for activating the multiplexer to transfer data from the first and second inputs to an output of the multiplexer.

To the accomplishment of the foregoing and related ends, the one or more embodiments include the features hereinafter fully described and particularly pointed out in the claims. The following description and the annexed drawings set forth in detail certain illustrative aspects of the one or more embodiments. These aspects are indicative, however, of but a few of the various ways in which the principles of various embodiments may be employed and the description embodiments are intended to include all such aspects and their equivalents.

### BRIEF DESCRIPTION OF THE DRAWINGS

FIG. 1 illustrates a block diagram of an exemplary digital interface circuit in accordance with an aspect of the disclosure.

FIG. 2 illustrates a block diagram of another exemplary digital interface circuit in accordance with another aspect of the disclosure.

FIG. 3A illustrates a block diagram of another exemplary digital interface circuit in accordance with another aspect of the disclosure.

FIG. 3B illustrates an exemplary table of various signals related to an operation of the digital interface circuit of FIG. 3A in accordance with another aspect of the disclosure.

FIG. 4A illustrates a block diagram of another exemplary digital interface circuit in accordance with another aspect of the disclosure.

FIG. 4B illustrates an exemplary table of various signals related to an operation of the digital interface circuit of FIG. 4A in accordance with another aspect of the disclosure.

FIG. 5A illustrates a block diagram of another exemplary digital interface circuit in accordance with another aspect of the disclosure.

FIG. 5B illustrates an exemplary table of various signals related to an operation of the digital interface circuit of FIG. 5A in accordance with another aspect of the disclosure.

FIG. 6 illustrates a block diagram of another exemplary digital interface circuit in accordance with another aspect of the disclosure.

FIG. 7 illustrates a block diagram of another exemplary digital interface circuit in accordance with another aspect of the disclosure.

FIG. 8 illustrates a flow diagram of an exemplary method of transferring data in accordance with another aspect of the disclosure.

### DETAILED DESCRIPTION

The detailed description set forth below, in connection with the appended drawings, is intended as a description of various configurations and is not intended to represent the only configurations in which the concepts described herein may be practiced. The detailed description includes specific details for the purpose of providing a thorough understanding of the various concepts. However, it will be apparent to those skilled in the art that these concepts may be practiced without these specific details. In some instances, well-known structures and components are shown in block diagram form in order to avoid obscuring such concepts.

An integrated circuit (IC) may include a set of distinct cores. The cores may operate under different voltage domains and clock domains. Often, these cores send data to each other. Because the cores operate under different voltage and clock domains, a digital interface circuit is often provided to convert the data from a first voltage-clock domain to a second voltage-clock domain when transferring data from a first core to a second core. Examples of such digital interface circuits are discussed below.

FIG. 1 illustrates a block diagram of an exemplary digital interface circuit 100 in accordance with an aspect of the disclosure. The digital interface circuit 100 depicted is for converting a single data bit from a first voltage-clock domain used in a first core 110 to a second voltage-clock domain used in a second core 150.

Usually, a set of parallel data bits are sent from the first core 110 to the second core 150. Accordingly, a portion of the digital interface circuit 110, namely a FIFO and a set of associated level shifters, is instantiated for each bit of the set of parallel data bits. The controllers and associated level shifters are instantiated once for the set of parallel data bits. Further, in accordance with this example, the first core 110 is on the “write” side as it is sending data to the second core 150, which is on the “read” side as it receiving the data from the first core 110.

The digital interface circuit 100 includes a write pointer controller 112, a read pointer controller 114, and a level shifter (LS) 116, all of which reside within the first core 110. The digital interface circuit 100 further includes a set of level shifters (LS) 160 to 168, a write pointer controller 152, a read pointer controller 154, a FIFO 156, and a logic circuit 158 coupled between the write pointer controller 152 and the read pointer controller 154.

The first core 110 generates a set of signals including write enable (we), write address (waddr), write data (wdata), and write clock (wclk), all of which are in a first voltage domain and a write clock (wclk) clock domain. The set of signals we, waddr, wdata, and wclk are used for writing data into the FIFO 156 of the second core 150. As these signals are in the first voltage domain, the set of level shifters (LS) 162 to 168 convert the signals we, waddr, wdata, and wclk into the second voltage domain prior to them being applied to the FIFO 156, respectively.

The write enable (we) signal is asserted each time data is to be written into the FIFO 156. The write address (waddr) points to a particular memory location (e.g., flip-flop or memory cell) in the FIFO 156 where the data is to be written. The write data (wdata) is the current data to be written into the FIFO 156. And, the write clock (wclk) synchronously controls the timing of the writing of the data into the FIFO 156.

The write pointer controller 112 of the first core 110 sends the write address (waddr) to the write pointer controller 152 of the second core 150 via the level shifter (LS) 160. The write pointer controller 152 keeps track of the memory locations in the FIFO 156 that have valid data to be read. The read pointer controller 154 communicates with the write pointer controller 152 via the logic circuit 158 to determine the read address (raddr) pointing to the memory location in the FIFO 156 having the next data to be read and to receive a read enable (ren) signal to initiate the reading of the data.

The read pointer controller 154 sends the read address (raddr) (or a related select signal) of the next data to be read to a select input of the FIFO 156 so that the FIFO outputs the corresponding read data rdata. After the data is read, the read pointer controller 154 of the second core 150 sends the read address (raddr) to the read pointer controller 114 of the first core 110 via the level shifter (LS) 116. The read pointer controller 114 sends the read address (raddr) to the write pointer controller 112 to indicate that the memory location associated with the read address (raddr) is now available to receive new data. Additionally, the read pointer controller 154 sends the read address (raddr) to the write pointer controller 152 via the logic circuit 158 so that the write pointer controller 152 invalidates the read address (raddr) as it no longer has data to be read.

An advantage of the digital interface circuit 100 is that it requires relatively few signals crossing the domain boundary per data bit. For instance, in this example, there are four (4) signals (we, waddr, wdata, and wclk) required to cross the domain boundary per each data bit. However, one disadvantage of the digital interface circuit 100 is that it is difficult to synchronously send (or close timing of) the signals crossing the domain boundary as the first and second cores 110 and 150 have different process corners. Additionally, it may be difficult to implement design for testability (DFT) features into the digital interface circuit 100.

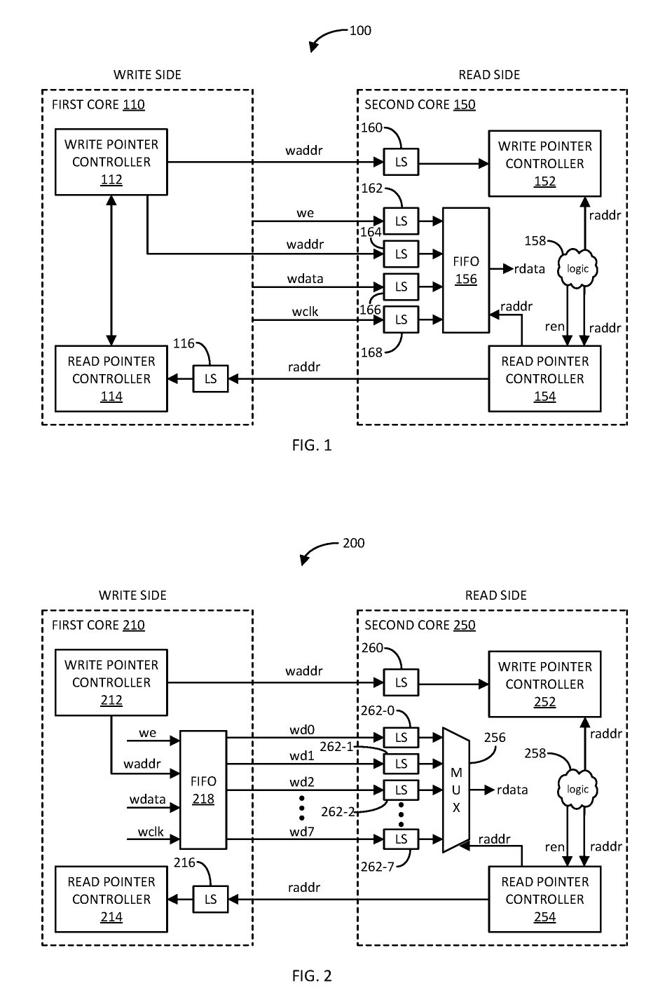

FIG. 2 illustrates a block diagram of another exemplary digital interface circuit 200 in accordance with another aspect of the disclosure. The digital interface circuit 200 includes similar elements as that of the digital interface circuit 100 previously discussed, such as the first core 210 including a write pointer controller 212, read pointer controller 214, and level shifter (LS) 216, and the second core 250 including a write pointer controller 252, associated level shifter (LS) 260, read pointer controller 254, and logic circuit 258.

The digital interface circuit 200 differs from digital interface circuit 100 in that the first core 210 includes a first-in-first-out (FIFO) memory 218 and the second core 250 includes a multiplexer (MUX) 256 with associated set of level shifters (LS) 262-0 to 262-7. Similarly, the signals we, waddr, wdata, and wclk are for writing data into the FIFO 218. The memory locations for storing data wd0 to wd7 in the FIFO 218 are coupled to inputs of the MUX 256 of the second core 250 via the set of level shifters (LS) 262-0 to 262-7, respectively.

The transferring of data from the first core 210 to the second core 250 operates as follows: Data (wdata) is written into the FIFO 218 using the signals we, waddr, and wclk. The data wd0 to wd7 written into the various locations in the FIFO 218 are applied to the inputs of the MUX 256 via the set of level shifters (LS) 262-0 to 262-7, respectively.

The write pointer controller 212 of the first core 210 sends the write address (waddr) to the write pointer controller 252 of the second core 250 via the level shifter (LS) 260. The write pointer controller 252 keeps track of the memory locations in the FIFO 218 that have valid data to be read. The read pointer controller 254 communicates with the write pointer controller 252 via the logic circuit 258 to determine the read address (raddr) pointing to the memory location in the FIFO 218 having the next data to be read and to receive a read enable (ren) signal to initiate the reading of the data.

The read pointer controller 254 sends the read address (raddr) (or related select signal) of the next data to be read to a select input of the MUX 256 so that the MUX outputs the corresponding read data rdata. After the data is read, the read pointer controller 254 of the second core 250 sends the read address (raddr) to the read pointer controller 214 of the first core 210 via the level shifter (LS) 216. The read pointer controller 214 sends the read address (raddr) to the write pointer controller 212 to indicate that the memory location associated with the read address (raddr) is now available to receive new data. Additionally, the read pointer controller 254 sends the read address (raddr) to the write pointer controller 252 via the logic circuit 258 so that the write pointer controller 252 invalidates the read address (raddr) as it no longer has data to be read.

An advantage of the digital interface circuit 200 is that signals for writing data to the FIFO 218 (namely, we, waddr, wdata, and wclk) do not cross the domain boundary. Thus, this avoids the synchronous or timing issues of sending such signals across the domain boundary as present in digital interface circuit 100. The digital interface circuit 200 may also be more easily configurable for design for testability (DFT).

A disadvantage of the digital interface circuit 200 is that there are more signals crossing the domain boundary than in digital interface circuit 100. As discussed, in digital interface circuit 100, there are four (4) signals crossing the domain boundary per data bit. In digital interface circuit 200, there are eight (8) signals crossing the domain boundary per data bit. In the case of a 128 parallel data interface, the digital interface circuit 200 would include at least 1024 (8×128) signal crossing, whereby each signal crossing would require a level shifter. This would result in the digital interface circuit 200 being relatively large and consuming substantial amount of power.

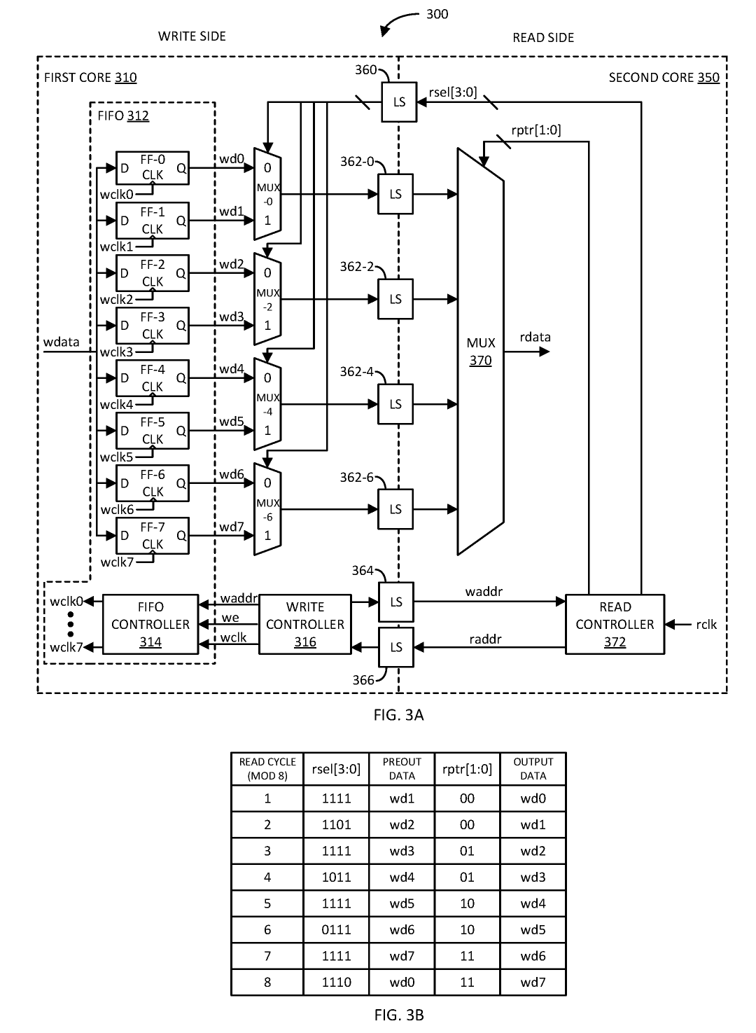

FIG. 3A illustrates a block diagram of another exemplary digital interface circuit 300 in accordance with another aspect of the disclosure. The digital interface circuit 300 includes a first core 310 having a FIFO memory 312 with a set of memory locations, such as flip-flops FF-0 to FF-7, and an associated FIFO controller 314. Although, in this example, the FIFO memory 312 includes eight (8) memory locations FF-0 to FF-7, it shall be understood that the FIFO memory may include more or less than eight (8) memory locations.

The first core 310 further includes a write controller 316 for controlling the writing of data into the FIFO 312. The write controller 316 generates write address (waddr), write enable (we), and substantially periodic base write clock (wclk) signals. These signals waddr, we, and wclk are applied to inputs of the FIFO controller 314. Based on these signals waddr, we, and wclk, the FIFO controller 314 generates clock signals wclk0 to wclk7. The clock signals wclk0 to wclk7 are applied to clock inputs (CLK) of the flip-flops FF-0 to FF-7, respectively. The write data (wdata) is applied to the data inputs (D) of the flip-flops FF-0 to FF-7.

The first core 310 further includes a set of two-input pre-multiplexers (“premuxes”) MUX-0, MUX-2, MUX-4, and MUX-6. The flip-flops FF-0 and FF-1 include data outputs (Q) coupled to inputs “0” and “1” of premux MUX-0; the flip-flops FF-2 and FF-3 include data outputs (Q) coupled to inputs “0” and “1” of premux MUX-2; the flip-flops FF-4 and FF-5 include data outputs (Q) coupled to inputs “0” and “1” of premux MUX-4; and the flip-flops FF-6 and FF-7 include data outputs (Q) coupled to inputs “0” and “1” of premux MUX-6.

The second core 350 includes a multiplexer (MUX) 370, associated level shifters (LS) 362-0 to 362-6, read controller 372, and associated level shifters 364 and 366. Although the level shifters 362-0 to 362-6 are described as being in the second core 350, it shall be understood that the first core 310 may include these level shifters. The premuxes MUX-0, MUX-2, MUX-4, and MUX-6 include outputs coupled to inputs of the MUX 370 via the level shifters 362-0, 362-2, 362-4, and 362-6, respectively.

The read controller 372 is configured to generate a first read control signal rsel[3:0]0 and a second read control signal rptr[1:0] based on a substantially periodic read clock signal (rclk). The four (4) lines of the first read control signal rsel[3:0] are applied to the select inputs of premuxes MUX-0 to MUX-6 via a set of level shifters (LS) 360 (one shown for simplicity purpose), respectively. The two (2) lines of the second read control signal rptr[1:0] are applied to the select input of MUX 370. The read controller 372 is configured to receive the write address (waddr) from the write controller 316 of the first core 310 via level shifter 364. The read controller 372 is further configured to send a read address (raddr) to the write controller 316 via level shifter 366.

The level shifters 360, 364, and 366 may be implemented in the first core 310, second core 350, or any combination thereof. The controllers 316 and 372 including the associated level shifters 360, 364, and 366 are common to all the parallel bits pertaining to the digital interface circuit 300.

The transferring of data by digital interface circuit 300 operates as follows: The write controller 316 keeps track of the next memory location in the FIFO 312 to which data is to be written. For instance, if the next memory location to which data is to be written is flip-flop FF-0, the write controller 316 generates a write address (waddr) pointing to flip-flop FF-0 and asserts the write enable (we) signal. In response to the write address (waddr) and the write enable (we) signal, the FIFO controller 314 generates the clock signal wclk0 based on the base clock signal wclk. In response to the clock signal wclk0, the current data (wdata) is written into the data output (Q) of flip-flop FF-0. This process of writing data into the FIFO 312 continues from flip-flop FF-0 to flip-flop FF-7 and back to flip-flop FF-0 in a round robin fashion.

When the write controller 316 causes data to be written into a particular memory location in the FIFO 312, the write controller 316 sends the write address (waddr) pointing to that memory location to the read controller 372 via the level shifter (LS) 364. Taking the above example, when data is written into flip-flop FF-0, the write controller 316 sends the write address (waddr) of the flip-flop FF-0 to the read controller 372. In response, the read controller 372 maintains a list of the memory locations of the FIFO 312 having valid data to be read.

The read controller 372 generates a first read control signal rsel[3:0] to control the selection made by the premuxes MUX-0, MUX-2, MUX-4, and MUX-6. For instance, the least significant bit (LSB) of the first read control signal rsel[3:0] controls the selection made by premux MUX-0. When the LSB transitions to a zero (0), the premux MUX-0 outputs sequential data wd0; when the LSB transitions to a one (1), the premux MUX-0 outputs sequential data wd1. Similarly, the second significant bit of the first read control signal rsel[3:0] controls the selection made by premux MUX-2. When the second significant bit transitions to zero (0), the premux MUX-2 outputs sequential data wd2; when the second significant bit transitions to a one (1), the premux MUX-2 outputs sequential data wd3.

In a like manner, the third significant bit of the first read control signal rsel[3:0] controls the selection made by premux MUX-4. When the third significant bit transitions to a zero (0), the premux MUX-4 outputs sequential data wd4; when the third significant bit transitions to a one (1), the premux MUX-4 outputs sequential data wd5. The most significant bit (MSB) of the first read control signal rsel[3:0] controls the selection made by premux MUX-6. When the MSB transitions to zero (0), the premux MUX-6 outputs sequential data wd6; when the MSB transitions to a one (1), the premux MUX-6 outputs sequential data wd7.

The read controller 372 generates a second read control signal rptr[1:0] to control the selection made by the MUX 370. For instance, when the second read control signal rptr[1:0] is 00, the MUX 370 outputs the sequential data wd0 or wd1 from the output of MUX-0. When the second read control signal rptr[1:0] is 01, the MUX 370 outputs the sequential data wd2 or wd3 from the output of MUX-2. When the second read control signal rptr[1:0] is 10, the MUX 370 outputs the sequential data wd4 or wd5 from the output of MUX-4. And, when the second read control signal rptr[1:0] is 11, the MUX 370 outputs the sequential data wd6 or wd7 from the output of MUX-6.

FIG. 3B illustrates an exemplary table of a modulo 8 read cycle index, the first read control signal rsel[3:01], the sequential data pre-outputted by a corresponding one of the premuxes MUX-0, MUX-2, MUX-4, and MUX-6, the second read control signal rptr[1:0], and the corresponding data outputted by the MUX 370 in accordance with another aspect of the disclosure.

For example, during read cycle one (1), the read controller 372 generates the first read control signal rsel[3:01] at 1111 and the second read control signal rptr[1:0] at 00. Because the LSB of the first read control signal rsel[3:0] transitioned to a one (1) (because the previous rsel[3:0] signal was at 1110), the premux MUX-0 outputs sequential data wd1. Also, during read cycle one (1), the read controller 372 generates the second read control signal rptr[1:0] at 00. This causes the MUX 370 to output sequential data wd0, which was at the output of MUX-0.

During read cycle two (2), the read controller 372 generates the first read control signal rsel[3:0] at 1101 and the second read control signal rptr[1:0] at 00. Because the second significant bit of the first read control signal rsel[3:0] transitioned to a zero (0) (because the previous rsel[3:0] signal was at 1111), the premux MUX-2 outputs sequential data wd2. Also, during read cycle two (2), the read controller 372 generates the second read control signal rptr[1:0] at 00. This causes the MUX 370 to output sequential data wd1.

The read controller 372 generates the first read control signal rsel[3:0] and second read control signal rptr[1:0] for the following read cycles three (3) to eight (8) in accordance with the table. The read controller 372 continues to generate these signals in a round robin (modulo 8) fashion for read cycles above eight (8). After each sequential data has been read or outputted by MUX 370 or outputted by any of the premuxes, the read controller 372 sends the corresponding read address (raddr) to the write controller 316. This informs the write controller 316 that the corresponding memory location in the FIFO 312 is available to receive new data.

Note, for consecutive read cycles eight (8) and one (1), the read controller 372 activates premux MUX-0; for consecutive read cycles two (2) and three (3), the read controller 372 activates premux MUX-2; for consecutive read cycles four (4) and five (5), the read controller 372 activates premux MUX-4; and for consecutive read cycles six (6) and (7), the read controller 372 activates premux MUX-6.

Accordingly, an issue with the digital circuit interface 300 is closing of the timing of the transfer of data from the first core 310 to the second core 350. As noted, each of the premuxes is activated for two consecutive cycles of a read clock (rclk). Due to the level shifting required for the rsel[3:0] signal and the level shifting of the data, it is difficult to meet timing requirements when a premux is activated for two consecutive read cycles. The following describes an implementation that addresses this issue.

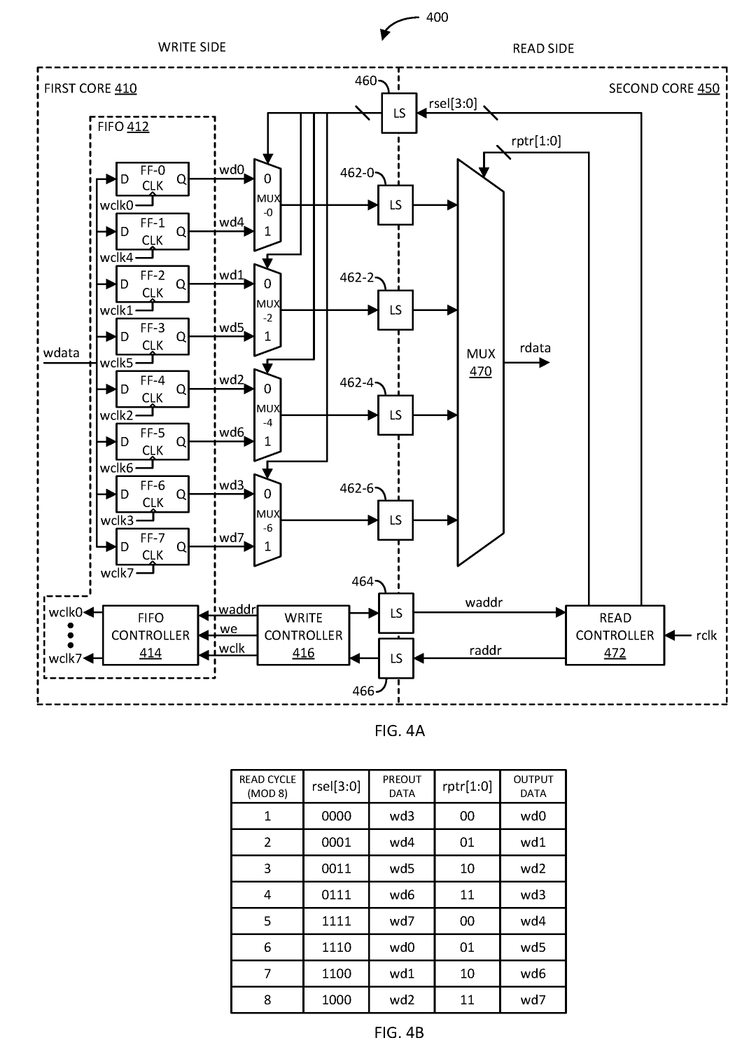

FIG. 4A illustrates a block diagram of another exemplary digital interface circuit 400 in accordance with another aspect of the disclosure. The digital interface circuit 400 is similar to that of digital interface circuit 300 except that writing of data into a FIFO is reordered to prevent the actuation of any of the premuxes for two consecutive read cycles. This is in contrast to the two consecutive read cycles performed on each of the premuxes of digital interface circuit 300 as previously discussed.

In particular, the digital interface circuit 400 includes a first core 410 and a second core 450. The first core 410 is on a write side as it is transferring data to the second core 450, which is on a read side.

The first core 410 includes a FIFO memory 412 including a set of memory locations or flip-flops FF-0 to FF-7. Again, although in this example, the FIFO memory 412 includes eight (8) memory locations, it shall be understood that the FIFO may include more or less than eight (8) memory locations. The FIFO memory 412 further includes a FIFO controller 414. Additionally, the first core 410 includes a set of four (4) two-input premuxes MUX-0, MUX-2, MUX-4, and MUX-6. Further, the first core 410 includes a write controller 416.

The write controller 416 is configured to control the writing of the current data (wdata) into the FIFO 412. In this regard, the write controller 416 is configured to generate a write address (waddr), write enable (we), and substantially periodic base write clock (wclk) signals. Based on these signals, the FIFO controller 414 generates write clock signals wclk0 to wclk7. In this case, the write clock signals wclk0 to wclk7 are applied to the clock inputs (CLK) of the flip-flops FF-0, FF-2, FF-4, FF-6, FF-1, FF-3, FF-5, and FF-7, respectively. As discussed in more detail below, the reordering of the application of the write clock signals wclk0 and wclk7 to the flip-flops in such manner (as compared to that of digital interface circuit 300) is to prevent the activation of any of the premuxes MUX-0, MUX-2, MUX-4, and MUX-6 for two consecutive read clock cycles. And, in particular, with this reordering, the premuxes MUX-0, MUX-2, MUX-4, and MUX-6 are each activated every fourth read clock cycle.

As in digital interface circuit 300, the current data (wdata) is applied to the data inputs (D) of the flip-flops FF-0 to FF-7. The flip-flops FF-0 and FF-1 include data outputs (Q) coupled to inputs “0” and “1” of premux MUX-0, respectively. The flip-flops FF-2 and FF-3 include data outputs (Q) coupled to inputs “0” and “1” of premux MUX-2, respectively. The flip-flops FF-4 and FF-5 include data outputs (Q) coupled to inputs “0” and “1” of premux MUX-4, respectively. The flip-flops FF-6 and FF-7 include data outputs (Q) coupled to inputs “0” and “1” of premux MUX-6, respectively.

The second core 450 includes a multiplexer (MUX) 470, associated level shifters (LS) 462-0 to 462-6, read controller 472, and associated level shifters 460, 464 and 466. Although the level shifters 462-0 to 462-6 are described as being in the second core 350, it shall be understood that the first core 310 may include these level shifters. The premuxes MUX-0, MUX-2, MUX-4, and MUX-6 include outputs coupled to inputs of the MUX 470 via the level shifters 462-0, 462-2, 462-4, and 462-6, respectively.

The read controller 472 is configured to generate a first read control signal rsel[3:0] and a second read control signal rptr[1:0] based on a substantially periodic read clock signal (rclk). The four (4) lines of the first control signal rsel[3:0] are applied to the select inputs of premuxes MUX-0 to MUX-6 via a set of level shifters (LS) 660 (one shown for simplicity purpose), respectively. The two (2) lines of the second read control signal rptr[1:0] are applied to the select input of MUX 470. The read controller 472 is configured to receive the write address (waddr) from the write controller 416 of the first core 410 via level shifter 464. The read controller 472 is further configured to send a read address (raddr) to the write controller 416 via level shifter 466.

The level shifters 460, 464, and 466 may be implemented in the first core 410, second core 450, or any combination thereof. The controllers 416 and 472 including the associated level shifters 460, 464, and 466 are common to all the parallel bits pertaining to the digital interface circuit 400.

The transferring of data by digital interface circuit 400 operates as follows: The write controller 416 keeps track of the memory location in the FIFO 412 into which the next data is to be written. For instance, if the next memory location to which data is to be written is flip-flop FF-0, the write controller 416 generates a write address (waddr) pointing to flip-flop FF-0 and asserts the write enable (we) signal. In response to the write address (waddr) and the write enable (we) signals, the FIFO controller 414 generates the clock signal wclk0 based on the base clock signal wclk. In response to the clock signal wclk0, the “first” sequential data (wdata) is written into the data output (Q) of flip-flop FF-0.

Because of the reordering as discussed above, the “second” sequential data to be written into the FIFO 412 goes to flip-flop FF-2 as it is clocked by write clock wclk1. The “third” sequential data to be written into the FIFO 412 goes to flip-flop FF-4 as it is clocked by write clock wclk2. The “fourth” sequential data to be written into the FIFO 412 goes to flip-flop FF-6 as it is clocked by write clock wclk3. The “fifth” sequential data to be written into the FIFO 412 goes to flip-flop FF-1 as it is clocked by write clock wclk4. The “sixth” sequential data to be written into the FIFO 412 goes to flip-flop FF-3 as it is clocked by write clock wclk5. The “seventh” sequential data to be written into the FIFO 412 goes to flip-flop FF-5 as it is clocked by write clock wclk6. The “eighth” sequential data to be written into the FIFO 412 goes to flip-flop FF-7 as it is clocked by write clock wclk7. The above process of sequentially writing data into the FIFO 412 continues in the aforementioned order in a round robin (modulo 8) fashion.

When the write controller 416 causes data to be written into a particular memory location in the FIFO 412, the write controller 416 sends the write address (waddr) pointing to that memory location to the read controller 472 via the level shifter (LS) 464. Taking the above example, when data is written into flip-flop FF-0, the write controller 416 sends the write address (waddr) of the flip-flop FF-0 to the read controller 472. In response, the read controller 472 maintains a list of the memory locations of the FIFO 412 having valid data to be read.

The read controller 472 generates the first read control signal rsel[3:0] to control the selection made by the premuxes MUX-0, MUX-2, MUX-4, and MUX-6. For instance, the least significant bit (LSB) of the first read control signal rsel[3:0] controls the selection made by premux MUX-0. When the LSB transitions to a zero (0), the premux MUX-0 outputs sequential data wd0; when the LSB transitions to a one (1), the premux MUX-0 outputs sequential data wd4. Similarly, the second significant bit of the first read control signal rsel[3:0] controls the selection made by premux MUX-2. When the second significant bit transitions to zero (0), the premux MUX-2 outputs sequential data wd1; when the second significant bit transitions to a one (1), the premux MUX-2 outputs sequential data wd5.

In a like manner, the third significant bit of the first read control signal rsel[3:0] controls the selection made by premux MUX-4. When the third significant bit transitions to a zero (0), the premux MUX-4 outputs sequential data wd2; when the third significant bit transitions to a one (1), the premux MUX-4 outputs sequential data wd6. The most significant bit (MSB) of the first read control signal rsel[3:0] controls the selection made by premux MUX-6. When the MSB transitions to zero (0), the premux MUX-6 outputs sequential data wd3; when the MSB transitions to a one (1), the premux MUX-6 outputs sequential data wd7.

The read controller 472 generates the second read control signal rptr[1:0] to control the selection made by the MUX 470. For instance, when the second read sub-address signal rptr[1:0] is 00, the MUX 470 outputs the sequential data wd0 or wd4 from the output of MUX-0. When the second read control signal rptr[1:0] is 01, the MUX 470 outputs the sequential data wd1 or wd5 from the output of MUX-2. When the second read control signal rptr[1:0] is 10, the MUX 470 outputs the sequential data wd2 or wd6 from the output of MUX-4. And, when the second read control signal rptr[1:0] is 11, the MUX 470 outputs the sequential data wd3 or wd7 from the output of MUX-6.

FIG. 4B illustrates an exemplary table of a modulo 8 read cycle index, the first read control signal rsel[3:0], the sequential data pre-outputted by a corresponding one of the premuxes MUX-0, MUX-2, MUX-4, and MUX-6, the second read control rptr[1:0], and the corresponding data outputted by the MUX 470 in accordance with another aspect of the disclosure.

For example, during read cycle one (1), the read controller 472 generates the first read control signal rsel[3:0] at 0000 and the second read control signal rptr[1:0] at 00. Because the MSB of the first read sub-address signal rsel[3:0] transitioned to a zero (0) (because the previous rsel[3:0] signal was at 1000), the premux MUX-6 outputs sequential data wd3. Also, during read cycle one (1), the read controller 472 generates the second read control signal rptr[1:0] at 00. This causes the MUX 470 to output sequential data wd0 from the output of premux MUX-0.

During read cycle two (2), the read controller 472 generates the first read control signal rsel[3:0] at 0001 and the second read control signal rptr[1:0] at 01. Because the LSB of the first read sub-address signal rsel[3:0] transitioned to a one (1) (because the previous rsel[3:0] signal was at 0000), the premux MUX-0 outputs sequential data wd4. Also, during read cycle two (2), the read controller 472 generates the second read control signal rptr[1:0] at 01. This causes the MUX 470 to output sequential data wd1 from the output of premux MUX-2.

The read controller 472 generates the first read control signal rsel[3:0] and second read control signal rptr[1:0] for the following read cycles three (3) to eight (8) in accordance with the table. The read controller 472 continues to generate these signals in a round robin (modulo 8) fashion above read cycle 8. Note, for read cycles one (1) to four (4) and five (5) to eight (8), the read controller 472 activates the premuxes in the following order: MUX-6, MUX-0, MUX-2, and MUX-4. Thus, none of the premuxes are activated for two consecutive read cycles.

Further, the MUX 470 outputs the sequential data after it has been pre-outputted by a premux three (3) read cycles prior. For example, in accordance with the table, the MUX 470 outputs sequential data wd3 in read cycle four (4). The premux MUX-6 pre-outputted the sequential data wd3 in read cycle one (1). Thus, the sequential data wd3 had three (3) read cycles to settle at the output of premux MUX-6. This allows the pre-outputted data at the outputs of the premuxes to settle for three (3) read cycles before it is read out by MUX 470. This reduces the likelihood of timing errors in the transfer of data from the first core 410 to the second core 450.

Thus, in this example, the activation of each of the premuxes occurs once every four cycles. Or, in other words, each of the bit line of the rsel[3:0] cycles at ¼ of the rate of the rptr signal at the read clock (rclk) rate. As this is a multicycle path, timing or synchronous problems with transferring the data from the first core 410 to the second core 450 are avoided or reduced.

After each sequential data has been read or outputted by MUX 470 or outputted by any of the premuxes, the read controller 472 sends the corresponding read address (raddr) to the write controller 416. This informs the write controller 416 that the corresponding memory location in the FIFO 412 is available to receive new data.

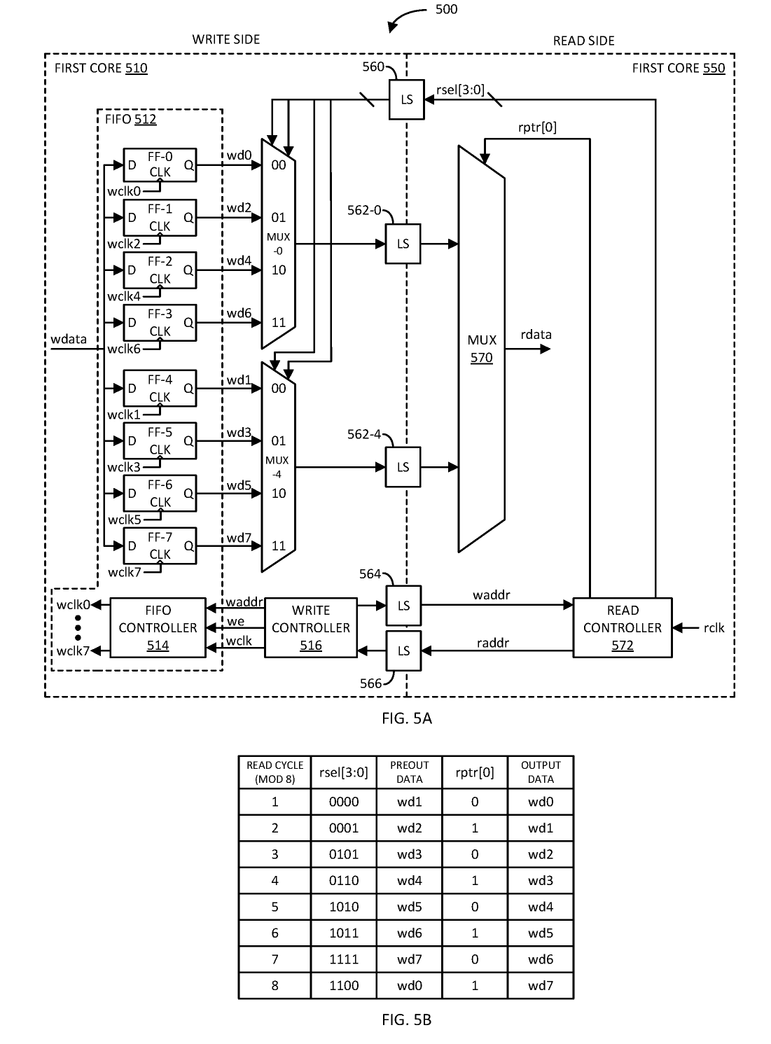

FIG. 5A illustrates a block diagram of another exemplary digital interface circuit 500 in accordance with another aspect of the disclosure. The digital interface circuit 500 is similar to digital interface circuit 400 except that digital interface circuit 500 includes two (2) four-input premuxes instead of four (4) two-input premuxes as in digital interface circuit 400. As discussed below in more detail, the digital interface circuit 500 is configured such that the premuxes are not activated for two consecutive read cycles so as to prevent timing issues.

In particular, the digital interface circuit 500 includes a first core 510 and a second core 550. The first core 510 is on a write side as it is transferring data to the second core 550, which is on a read side.

The first core 510 includes a FIFO memory 512 including a set of memory locations or flip-flops FF-0 to FF-7. Again, although in this example, the FIFO memory 512 includes eight (8) memory locations, it shall be understood that the FIFO may include more or less than eight (8) memory locations. The FIFO memory 512 further includes a FIFO controller 514. Additionally, the first core 510 includes a set of two (2) four-input premuxes MUX-0 and MUX-4. Further, the first core 510 includes a write controller 516.

The write controller 516 is configured to control the writing of the current data (wdata) into the FIFO 512. In this regard, the write controller 516 is configured to generate a write address (waddr), write enable (we), and substantially periodic base write clock (wclk) signals. Based on these signals, the FIFO controller 514 generates write clock signals wclk0 to wclk7. In this case, the write clock signals wclk0 to wclk7 are applied to the clock inputs (CLK) of the flip-flops FF-0, FF-4, FF-1, FF-5, FF-2, FF-6, FF-3, and FF-7, respectively. As discussed in more detail below, this ordering of the application of the write clock signals wclk0 and wclk7 to the flip-flops in such manner is to prevent the activation of each of premuxes MUX-0 and MUX-4 for two consecutive read clock cycles. And, in particular, the premuxes MUX-0 and MUX-4 are each activated every other read clock cycle.

The current data (wdata) is applied to the data inputs (D) of the flip-flops FF-0 to FF-7.

The flip-flops FF-0, FF-1, FF-2, and FF-3 include data outputs (Q) coupled to inputs “00”, “01”, “10”, and “11” of premux MUX-0, respectively. The flip-flops FF-4, FF-5, FF-6, and FF-7 include data outputs (Q) coupled to inputs “00”, “01”, “10”, and “11” of premux MUX-4, respectively.

The second core 550 includes a multiplexer (MUX) 570, associated level shifters (LS) 562-0 and 562-4, read controller 572, and associated level shifters 560, 564 and 566. Although the level shifters 562-0 and 562-4 are described as being in the second core 550, it shall be understood that the first core 510 may include these level shifters. The premuxes MUX-0 and MUX-4 include outputs coupled to inputs of the MUX 570 via the level shifters 562-0 and 562-4, respectively.

The read controller 572 is configured to generate a first read control signal rsel[3:0] and a second read control signal rptr[0] based on a substantially periodic read clock signal (rclk). The two (2) lines of the first read control signal rsel[3:0] are applied to the select input of premux MUX-0 via a set of level shifters (LS) 560 (one shown for simplicity purpose. The other two (2) lines of the first read control signal rsel[3:0] are applied to the select input of premux MUX-4 via the set of level shifters (LS) 560. The second read control signal rptr[0] is applied to the select input of MUX 570.

The read controller 572 is configured to receive the write address (waddr) from the write controller 516 of the first core 510 via level shifter 564. The read controller 572 is further configured to send a read address (raddr) to the write controller 516 via level shifter 566. The level shifters 560, 564, and 566 may be implemented in the first core 510, second core 550, or any combination thereof. The controllers 516 and 572 including the associated level shifters 560, 564, and 566 are common to all the parallel bits pertaining to the digital interface circuit 500.

The transferring of data by digital interface circuit 500 operates as follows: The write controller 516 keeps track of the memory location in the FIFO 512 into which the next data is to be written. For instance, if the next memory location to which data is to be written is flip-flop FF-0, the write controller 516 generates a write address (waddr) pointing to flip-flop FF-0 and asserts the write enable (we) signal. In response to the write address (waddr) and the write enable (we) signals, the FIFO controller 514 generates the clock signal wclk0 based on the base clock signal wclk. In response to the clock signal wclk0, the “first” sequential data (wdata) is written into the data output (Q) of flip-flop FF-0.

Because of the ordering as discussed above, the “second” sequential data to be written into the FIFO 512 goes to flip-flop FF-4 as it is clocked by write clock wclk1. The “third” sequential data to be written into the FIFO 512 goes to flip-flop FF-1 as it is clocked by write clock wclk2. The “fourth” sequential data to be written into the FIFO 512 goes to flip-flop FF-5 as it is clocked by write clock wclk3. The “fifth” sequential data to be written into the FIFO 412 goes to flip-flop FF-2 as it is clocked by write clock wclk4. The “sixth” sequential data to be written into the FIFO 512 goes to flip-flop FF-6 as it is clocked by write clock wclk5. The “seventh” sequential data to be written into the FIFO 512 goes to flip-flop FF-3 as it is clocked by write clock wclk6. The “eighth” sequential data to be written into the FIFO 512 goes to flip-flop FF-7 as it is clocked by write clock wclk7. The above process of sequentially writing data into the FIFO 512 continues in the aforementioned order in a round robin (modulo 8) fashion.

When the write controller 516 causes data to be written into a particular memory location in the FIFO 512, the write controller 516 sends the write address (waddr) pointing to that memory location to the read controller 572 via the level shifter (LS) 564. Taking the above example, when data is written into flip-flop FF-0, the write controller 516 sends the write address (waddr) of the flip-flop FF-0 to the read controller 572. In response, the read controller 572 maintains a list of the memory locations of the FIFO 412 having valid data to be read.

The read controller 572 generates the first read control signal rsel[3:0] to control the selection made by the premuxes MUX-0 and MUX-4. For instance, the two least significant bits (LSBs) of the first read sub-address signal rsel[3:0] controls the selection made by premux MUX-0. When the two LSBs transitions to a “00”, the premux MUX-0 outputs sequential data wd0; when the two LSBs transitions to a “01”, the premux MUX-0 outputs sequential data wd2; when the two LSBs transitions to a “10”, the premux MUX-0 outputs sequential data wd4; and when the two LSBs transitions to a “11”, the premux MUX-0 outputs sequential data wd6.

Similarly, the two most significant bits (MSBs) of the first read control signal rsel[3:0] controls the selection made by premux MUX-4. When the two MSBs transitions to a “00”, the premux MUX-4 outputs sequential data wd1; when the two MSBs transitions to a “01”, the premux MUX-4 outputs sequential data wd3; when the two MSBs transitions to a “10”, the premux MUX-4 outputs sequential data wd5; and when the two MSBs transitions to a “11”, the premux MUX-4 outputs sequential data wd7.

The read controller 572 generates the second read control signal rptr[0] to control the selection made by the MUX 570. For instance, when the second read control signal rptr[0] is zero (0), the MUX 570 outputs the sequential data wd0, wd2, wd4, or wd6 from the output of MUX-0. When the second read control signal rptr[0] is one (1), the MUX 570 outputs the sequential data wd1, wd3, wd5, or wd7 from the output of MUX-4.

FIG. 5B illustrates an exemplary table of a modulo 8 read cycle index, the first read control signal rsel[3:0], the sequential data pre-outputted by a corresponding one of the premuxes MUX-0 and MUX-4, the second read control rptr[0], and the corresponding data outputted by the MUX 570 in accordance with another aspect of the disclosure.

For example, during read cycle one (1), the read controller 572 generates the first read control signal rsel[3:0] at 0000 and the second read control signal rptr[0] at 0. Because the two MSBs of the first read control signal rsel[3:0] transitioned to a “00” (because the previous rsel[3:0] signal was at 1100), the premux MUX-4 outputs sequential data wd1. Also, during read cycle one (1), the read controller 572 generates the second read control signal rptr[0] at zero (0). This causes the MUX 570 to output sequential data wd0 from the output of premux MUX-0.

During read cycle two (2), the read controller 572 generates the first read control signal rsel[3:0] at 0001 and the second read control signal rptr[0] at one (1). Because the two LSBs of the first read control signal rsel[3:0] transitioned to a “01” (because the previous rsel[3:0]0 signal was at 0000), the premux MUX-0 outputs sequential data wd2. Also, during read cycle two (2), the read controller 572 generates the second read control signal rptr[0] at one (1). This causes the MUX 570 to output sequential data wd1 from the output of premux MUX-4.

The read controller 572 generates the first read control signal rsel[3:0] and second read control signal rptr[0] for the following read cycles three (3) to eight (8) in accordance with the table. The read controller 572 continues to generate these signals in a round robin (modulo 8) fashion above read cycle eight (8). As indicated in the table, the read controller 572 activates the premuxes MUX-0 and MUX-4 in an alternating manner. Thus, none of the premuxes are activated for two consecutive read cycles.

Further, the MUX 570 outputs the sequential data after it has been pre-outputted by a premux in the previous read cycle. For example, in accordance with the table, the MUX 570 outputs sequential data wd3 in read cycle four (4). The premux MUX-4 pre-outputted the sequential data wd3 in read cycle three (3). Thus, the sequential data wd3 had one read cycle to settle at the output of premux MUX-4. This allows the pre-outputted data at the outputs of the premuxes to settle for one (1) read cycle before it is read out by MUX 570. This reduces the likelihood of timing errors in the transfer of data from the first core 510 to the second core 550.

Thus, in this example, the activation of each of the premuxes occurs once every two read cycles. Or, in other words, each of the two LSBs and two MSBs of the rsel[3:0] signal cycles at ½ of the rate of the rptr signal at the read clock (rclk) rate. As this is a multicycle path, timing or synchronous problems with transferring the data from the first core 510 to the second core 550 are avoided or reduced.

After each sequential data has been read or outputted by MUX 570 or outputted by any of the premuxes, the read controller 572 sends the corresponding read address (raddr) to the write controller 516. This informs the write controller 516 that the corresponding memory location in the FIFO 512 is available to receive new data.

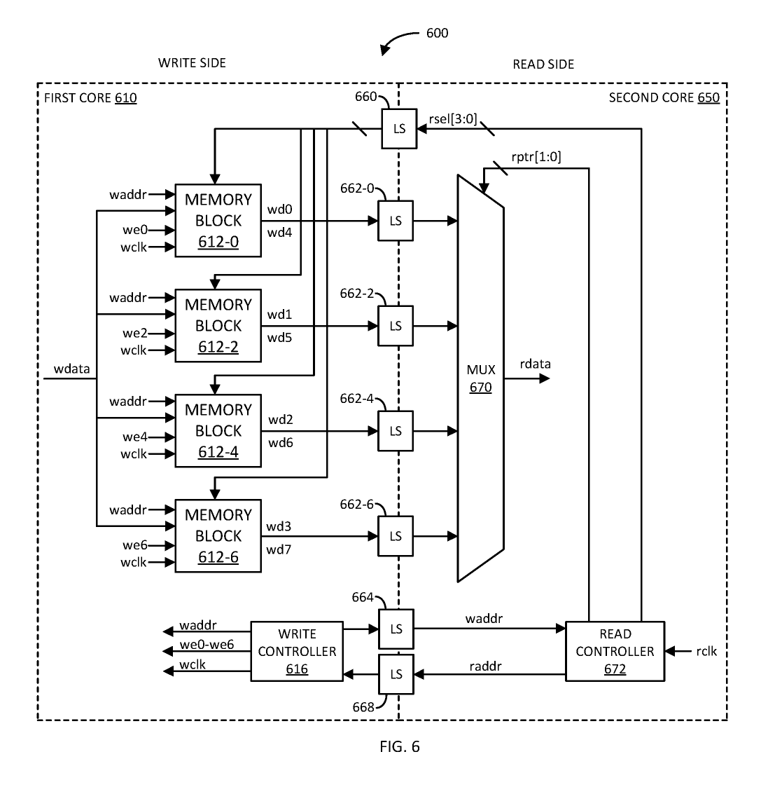

FIG. 6 illustrates a block diagram of another exemplary digital interface circuit 600 in accordance with another aspect of the disclosure. The digital interface circuit 600 is similar to that of digital interface circuit 400 except that memory blocks 612-0 to 612-6 in digital interface circuit 600 replace the FIFO 412 and premuxes MUX-0 to MUX-6 in digital interface circuit 400.

In other words, the flip-flops FF-0 and FF-1 of the FIFO 412 coupled to premux MUX-0 may be considered a memory block, such as memory block 612-0. Similarly, the flip-flops FF-2 and FF-3 of the FIFO 412 coupled to premux MUX-2 may be considered another memory block, such as memory block 612-2. The flip-flops FF-4 and FF-5 of the FIFO 412 coupled to premux MUX-4 may be considered another memory block, such as memory block 612-4. And, the flip-flops FF-6 and FF-7 of the FIFO 412 coupled to premux MUX-6 may be considered another memory block, such as memory block 612-6.

In particular, the digital interface circuit 600 includes a first core 610 and a second core 650. The first core 610 is on a write side as it is transferring data to the second core 650, which is on a read side.

The first core 610 includes a set of memory blocks 612-0 to 612-6 and a write controller 616. The write controller 616 is configured to control the writing of the current data (wdata) into the memory blocks 612-0 to 612-6. In this regard, the write controller 616 is configured to generate a write address (waddr), write enable (we0 to we6), and substantially periodic base write clock (wclk) signals. Based on these signals, current data (wdata) is written into the memory blocks 612-0 to 612-6.

For example, when writing sequential data wd0 or wd4 into memory block 612-0, the write controller 616 generates a write address (waddr) pointing to a memory location for storing the data, asserts the write enable (we0), and continuously generates the write clock (wclk). When writing sequential data wd1 or wd5 into memory block 612-2, the write controller 616 generates a write address (waddr) pointing to a memory location for storing the data, asserts the write enable (we2), and continuously generates the write clock (wclk). When writing sequential data wd2 or wd6 into memory block 612-4, the write controller 616 generates a write address (waddr) pointing to a memory location for storing the data, asserts the write enable (we4), and continuously generates the write clock (wclk). When writing sequential data wd3 or wd7 into memory block 612-0, the write controller 616 generates a write address (waddr) pointing to a memory location for storing the data, asserts the write enable (we6), and continuously generates the write clock (wclk).

The second core 650 includes a multiplexer (MUX) 670, associated level shifters (LS) 662-0 to 662-6, read controller 672, and associated level shifters 660, 664 and 668. Although the level shifters 662-0 to 662-6 are described as being in the second core 650, it shall be understood that the first core 610 may include these level shifters. The memory blocks 612-0, 612-2, 612-4, and 612-6 include outputs coupled to inputs of the MUX 670 via the level shifters 662-0, 662-2, 662-4, and 662-6, respectively.

The read controller 672 is configured to generate a first read control rsel[3:0] and a second read control rptr[1:0]. The four (4) lines of the first control rsel[3:0] are applied to the select inputs of memory blocks 612-0, 612-2, 612-4, and 612-6, respectively. The two (2) lines of the second read control rptr[1:0] are applied to the select input of MUX 670. The read controller 672 is configured to receive the write address (waddr) from the write controller 616 of the first core 610 via level shifter 664. The read controller 672 is further configured to send a read address (raddr) to the write controller 616 via level shifter 668.

The level shifters 660, 664, and 668 may be implemented in the first core 610, second core 650, or any combination thereof. The controllers 616 and 672 including the associated level shifters 660, 664, and 668 are common to all the parallel bits pertaining to the digital interface circuit 600.

The writing and reading operation of the digital interface circuit 600 is similar to that of digital interface circuit 400, and the corresponding table shown in FIG. 4B applies to digital interface circuit 600. Thus, the activation of each of the memory blocks 612-0, 612-2, 612-4, and 612-6 occurs once every four read cycles. Or, in other words, each of the bit line of the rsel[3:0] signal cycles at ¼ of the rate of the rptr signal at a read clock (rclk) rate. As this is a multicycle path, timing or synchronous problems with transferring the data from the first core 610 to the second core 650 are avoided or reduced.

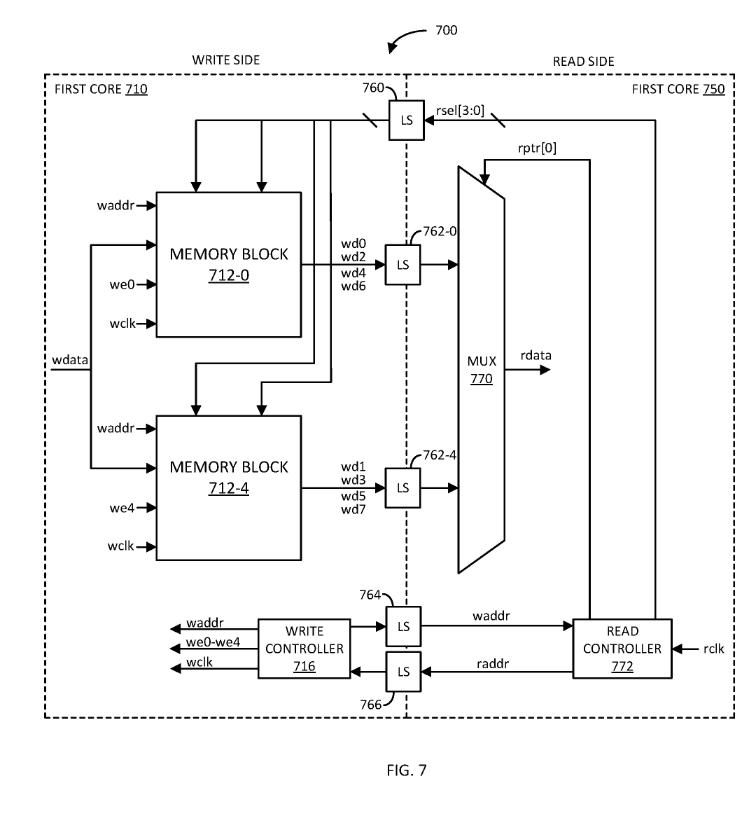

FIG. 7 illustrates a block diagram of another exemplary digital interface circuit 700 in accordance with another aspect of the disclosure. The digital interface circuit 700 is similar to that of digital interface circuit 500 except that memory blocks 712-0 and 712-4 in digital interface circuit 700 replace the FIFO 412 and premuxes MUX-0 and MUX-4 in digital interface circuit 500. In other words, the flip-flops FF-0 to FF-3 of the FIFO 512 coupled to premux MUX-0 may be considered a memory block, such as memory block 712-0. And, the flip-flops FF-4 to FF-7 of the FIFO 512 coupled to premux MUX-4 may be considered another memory block, such as memory block 712-4.

In particular, the digital interface circuit 700 includes a first core 710 and a second core 750. The first core 710 is on a write side as it is transferring data to the second core 750, which is on a read side.

The first core 710 includes memory blocks 712-0 and 712-4 and a write controller 716. The write controller 716 is configured to control the writing of the current data (wdata) into the memory blocks 712-0 and 712-4. In this regard, the write controller 716 is configured to generate a write address (waddr), write enable (we0 and we4), and substantially periodic base write clock (wclk) signals. Based on these signals, current data (wdata) is written into the memory blocks 712-0 and 712-6.

For example, when sequential data wd0, wd2, wd4, or wd4 is written into memory block 712-0, the write controller 716 generates a write address (waddr) pointing to a memory location for storing the data, asserts the write enable (we0), and continuously generates the write clock (wclk). When sequential data wd1, wd3, wd5, or wd7 is written into memory block 712-4, the write controller 716 generates a write address (waddr) pointing to a memory location for storing the data, asserts the write enable (we4), and continuously generates the write clock (wclk).

The second core 750 includes a multiplexer (MUX) 770, associated level shifters (LS) 762-0 and 762-4, read controller 772, and associated level shifters 760, 764 and 766. Although the level shifters 762-0 and 762-4 are described as being in the second core 750, it shall be understood that the first core 710 may include these level shifters. The memory blocks 712-0 and 712-4 include outputs coupled to inputs of the MUX 770 via the level shifters 762-0 and 762-4, respectively.

The read controller 772 is configured to generate a first read control rsel[3:0] and a second read control rptr[0]. The two LSBs and the two MSBs of the first control signal rsel[3:0] are applied to the select inputs of memory blocks 712-0 and 712-4, respectively. The second read control signal rptr[0] is applied to the select input of MUX 770. The read controller 772 is configured to receive the write address (waddr) from the write controller 716 of the first core 710 via level shifter 764. The read controller 772 is further configured to send a read address (raddr) to the write controller 716 via level shifter 766.

The level shifters 760, 764, and 766 may be implemented in the first core 710, second core 750, or any combination thereof. The controllers 716 and 772 including the associated level shifters 760, 764, and 766 are common to all the parallel bits pertaining to the digital interface circuit 700.

The writing and reading operation of the digital interface circuit 700 is similar to that of digital interface circuit 500, and the corresponding table shown in FIG. 5B applies to digital interface circuit 700. Thus, the activation of each of the memory blocks 712-0 and 712-4 occurs every other read cycle. Or, in other words, each of the two LSBs and two MSBs of the rsel[3:0] cycles at ½ of the rate of the rptr[0] signal at a read clock (rclk) rate. As this is a multicycle path, timing or synchronous problems with transferring the data from the first core 710 to the second core 750 are avoided or reduced.

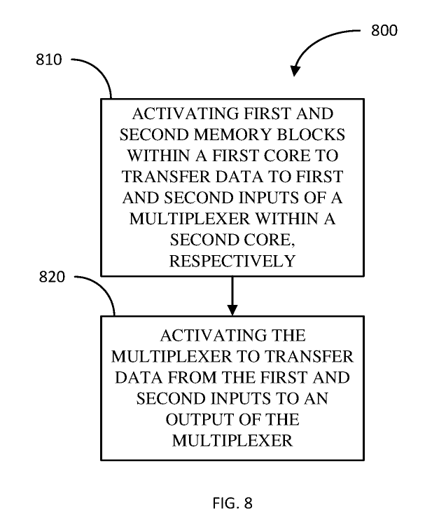

FIG. 8 illustrates a flow diagram of an exemplary method 800 of transferring data in accordance with another aspect of the disclosure. The method 800 includes activating first and second memory blocks within a first core to transfer data to first and second inputs of a multiplexer within a second core, respectively (block 810). Examples of means for activating first and second memory blocks within a first core to transfer data to first and second inputs of a multiplexer within a second core include read controllers 372, 472, 572, 672, and 772 generating the first read control signal rsel[3:0].

The method 800 further includes activating the multiplexer to transfer data from the first and second inputs to an output of the multiplexer (block 820). Examples of means for activating the multiplexer to transfer data from the first and second inputs to an output of the multiplexer include read controllers 372, 472, 572, 672, and 772 generating the second read control signal rptr[1:0] or rptr[0].

The previous description of the disclosure is provided to enable any person skilled in the art to make or use the disclosure. Various modifications to the disclosure will be readily apparent to those skilled in the art, and the generic principles defined herein may be applied to other variations without departing from the spirit or scope of the disclosure. Thus, the disclosure is not intended to be limited to the examples described herein but is to be accorded the widest scope consistent with the principles and novel features disclosed herein.

What is claimed is:

1. An apparatus, comprising:
a first core comprising:
a first memory block; and
a second memory block;
a second core comprising:
a multiplexer including first and second inputs coupled to the first and second memory blocks, respectively; and
a read controller configured to:
generate a first read control signal to cause the first and second memory blocks to transfer data to the first and second inputs of the multiplexer, respectively; and
generate a second read control signal to cause the multiplexer to transfer data from the first and second inputs to an output of the multiplexer.

2. The apparatus of claim 1, wherein the read controller is further configured to:
generate the first read control signal to cause the first memory block to transfer data to the first input of the multiplexer during a first clock cycle in which the second memory block does not transfer data to the second input of the multiplexer;
generate the first read control signal to cause the second memory block to transfer data to the second input of the multiplexer during a second clock cycle in which the first memory block does not transfer data to the first input of the multiplexer;
generate the second read control signal to cause the multiplexer to transfer data from the second input to the output of the multiplexer during the first clock cycle; and
generate the second read control signal to cause the multiplexer to transfer data from the first input to the output of the multiplexer during the second clock cycle.

3. The apparatus of claim 1, wherein the first memory block comprises:
a first pre-multiplexer; and
a first set of memory locations of a memory device, wherein the first set of memory locations are coupled to the first pre-multiplexer.

4. The apparatus of claim 3, wherein the second memory block comprises:
a second pre-multiplexer; and
a second set of memory locations of the memory device, wherein the second set of memory locations are coupled to the second pre-multiplexer.

5. The apparatus of claim 4, wherein the memory device comprises a first-in-first-out (FIFO) memory.

6. The apparatus of claim 1, wherein:
the first core further comprises a third memory block and a fourth memory block;
the multiplexer includes third and fourth inputs coupled to third and fourth outputs of the third and fourth memory blocks, respectively; and
the read controller is further configured to generate the first read control signal to cause the third and fourth memory blocks to transfer data to the third and fourth inputs of the multiplexer, respectively.

7. The apparatus of claim 6, wherein the read controller is further configured to:
generate the first read control signal to cause the first memory block to transfer data to the first input of the multiplexer during a first clock cycle in which the second, third, and fourth memory blocks do not transfer data to the second, third, and fourth inputs of the multiplexer, respectively;
generate the first read control signal to cause the second memory block to transfer data to the second input of the multiplexer during a second clock cycle in which the first, third, and fourth memory blocks do not transfer data to the first, third, and fourth inputs of the multiplexer, respectively;
generate the first read control signal to cause the third memory block to transfer data to the third input of the multiplexer during a third clock cycle in which the first, second, and fourth memory blocks do not transfer data to the first, second, and fourth inputs of the multiplexer, respectively; and
generate the first read control signal to cause the fourth memory block to transfer data to the fourth input of the multiplexer during a fourth clock cycle in which the first, second, and third memory blocks do not transfer data to the first, second, and third inputs of the multiplexer, respectively.

8. The apparatus of claim 7, wherein the read controller is further configured to:
generate the second read control signal to cause the multiplexer to transfer data from the second input to the output of the multiplexer during the first clock cycle;
generate the second read control signal to cause the multiplexer to transfer data from the third input to the output of the multiplexer during the second clock cycle;
generate the second read control signal to cause the multiplexer to transfer data from the fourth input to the output of the multiplexer during the third clock cycle; and
generate the second read control signal to cause the multiplexer to transfer data from the first input to the output of the multiplexer during the fourth clock cycle.

9. The apparatus of claim 6, wherein:
the first memory block comprises:
a first pre-multiplexer; and
a first set of memory locations of a memory device, wherein the first set of memory locations are coupled to the first pre-multiplexer;
the second memory block comprises:
a second pre-multiplexer; and
a second set of memory locations of the memory device, wherein the second set of memory locations are coupled to the second pre-multiplexer;
the third memory block comprises:
a third pre-multiplexer; and
a third set of memory locations of the memory device, wherein the third set of memory locations are coupled to the third pre-multiplexer; and
the fourth memory block comprises:
a fourth pre-multiplexer; and
a fourth set of memory locations of the memory device, wherein the fourth set of memory locations are coupled to the fourth pre-multiplexer.

10. The apparatus of claim 9, wherein the memory device comprises a first-in-first-out (FIFO) memory.

11. A method, comprising:
activating first and second memory blocks within a first core to transfer data to first and second inputs of a multiplexer within a second core; and
activating the multiplexer to transfer data from the first and second inputs to an output of the multiplexer.

12. The method of claim 11, wherein activating the first and second memory blocks comprises:
activating the first memory block to transfer data to the first input of the multiplexer during a first clock cycle in which the second memory block does not transfer data to the second input of the multiplexer; and
activating the second memory block to transfer data to the second input of the multiplexer during a second clock cycle in which the first memory block does not transfer data to the first input of the multiplexer.

13. The method of claim 12, wherein activating the multiplexer comprises:
activating the multiplexer to transfer data from the second input to the output of the multiplexer during the first clock cycle; and
activating the multiplexer to transfer data from the first input to the output of the multiplexer during the second clock cycle.

14. The method of claim 11, wherein activating the first memory block comprises:
activating one of a first set of memory locations of a memory device to transfer data to an input of a first pre-multiplexer; and
activating the first pre-multiplexer to transfer data to the first input of the multiplexer.

15. The method of claim 14, wherein activating the second memory block comprises:
activating one of a second set of memory locations of the memory device to transfer data to an input of a second pre-multiplexer; and
activating the second pre-multiplexer to transfer data to the second input of the multiplexer.

16. The method of claim 11, further comprising activating third and fourth memory blocks to transfer data to third and fourth inputs of the multiplexer, respectively.

17. The method of claim 16, wherein:
activating the first memory block comprises activating the first memory block to transfer data to the first input of the multiplexer during a first clock cycle in which the second, third, and fourth memory blocks do not transfer data to the second, third, and fourth inputs of the multiplexer, respectively;
activating the second memory block comprises activating the second memory block to transfer data to the second input of the multiplexer during a second clock cycle in which the first, third, and fourth memory blocks do not transfer data to the first, third, and fourth inputs of the multiplexer, respectively;
activating the third memory block comprises activating the third memory block to transfer data to the third input of the multiplexer during a third clock cycle in which the first, second, and fourth memory blocks do not transfer data to the first, second, and fourth inputs of the multiplexer, respectively; and
activating the fourth memory block comprises activating the fourth memory block to transfer data to the fourth input of the multiplexer during a fourth clock cycle in which the first, second, and third memory blocks do not transfer data to the first, second, and third inputs of the multiplexer, respectively.

18. The method of claim 17, wherein activating the multiplexer comprises:
activating the multiplexer to transfer data from the second input to the output of the multiplexer during the first clock cycle;
activating the multiplexer to transfer data from the third input to the output of the multiplexer during the second clock cycle;
activating the multiplexer to transfer data from the fourth input to the output of the multiplexer during the third clock cycle; and
activating the multiplexer to transfer data from the first input to the output of the multiplexer during the fourth clock cycle.

19. The method of claim 16, wherein:
activating the first memory block comprises:
activating one of a first set of memory locations of a memory device to transfer data to an input of a first pre-multiplexer; and
activating the first pre-multiplexer to transfer data to the first input of the multiplexer;
activating the second memory block comprises:
activating one of a second set of memory locations of the memory device to transfer data to an input of a second pre-multiplexer; and
activating the second pre-multiplexer to transfer data to the second input of the multiplexer;
activating the third memory block comprises:
activating one of a third set of memory locations of the memory device to transfer data to an input of a third pre-multiplexer; and
activating the third pre-multiplexer to transfer data to the third input of the multiplexer; and
activating the fourth memory block comprises:
activating one of a fourth set of memory locations of the memory device to transfer data to an input of a fourth pre-multiplexer; and
activating the fourth pre-multiplexer to transfer data to the fourth input of the multiplexer.

20. The method of claim 19, wherein the memory device comprises a first-in-first-out (FIFO) memory.

21. An apparatus, comprising:
means for activating first and second memory blocks within a first core to transfer data to first and second inputs of a multiplexer within a second core, respectively; and
means for activating the multiplexer to transfer data from the first and second inputs to an output of the multiplexer.

22. The apparatus of claim 21, wherein the means for activating the first and second memory blocks comprises:
means for activating the first memory block to transfer data to the first input of the multiplexer during a first clock cycle in which the second memory block does not transfer data to the second input of the multiplexer; and
means for activating the second memory block to transfer data to the second input of the multiplexer during a second clock cycle in which the first memory block does not transfer data to the first input of the multiplexer.

23. The apparatus of claim 22, wherein the means for activating the multiplexer comprises:
means for activating the multiplexer to transfer data from the second to the output of the multiplexer during the first clock cycle; and
means for activating the multiplexer to transfer data from the first input to the output of the multiplexer during the second clock cycle.

24. The apparatus of claim 21, wherein the means for activating the first memory block comprises:
means for activating one of a first set of memory locations of a memory device to transfer data to an input of a first pre-multiplexer; and
means for activating the first pre-multiplexer to transfer data to the first input of the multiplexer.

25. The apparatus of claim 24, wherein the means for activating the second memory block comprises:
means for activating one of a second set of memory locations of the memory device to transfer data to an input of a second pre-multiplexer; and
means for activating the second pre-multiplexer to transfer data to the second input of the multiplexer.

26. The apparatus of claim 21, further comprising means for activating third and fourth memory blocks to transfer data to third and fourth inputs of the multiplexer, respectively.

27. The apparatus of claim 26, wherein:
the means for activating the first memory block comprises means for activating the first memory block to transfer data to the first input of the multiplexer during a first clock cycle in which the second, third, and fourth memory blocks do not transfer data to the second, third, and fourth inputs of the multiplexer, respectively;
the means for activating the second memory block comprises means for activating the second memory block to transfer data to the second input of the multiplexer during a second clock cycle in which the first, third, and fourth memory blocks do not transfer data to the first, third, and fourth inputs of the multiplexer, respectively;
the means for activating the third memory block comprises means for activating the third memory block to transfer data to the third input of the multiplexer during a third clock cycle in which the first, second, and fourth memory blocks do not transfer data to the first, second, and fourth inputs of the multiplexer, respectively; and
the means for activating the fourth memory block comprises means for activating the fourth memory block to transfer data to the fourth input of the multiplexer during a fourth clock cycle in which the first, second, and third memory blocks do not transfer data to the first, second, and third inputs of the multiplexer, respectively.

28. The apparatus of claim 27, wherein the means for activating the multiplexer comprises:
means for activating the multiplexer to transfer data from the second to the output of the multiplexer during the first clock cycle;
means for activating the multiplexer to transfer data from the third input to the output of the multiplexer during the second clock cycle;
means for activating the multiplexer to transfer data from the fourth input to the output of the multiplexer during the third clock cycle; and
means for activating the multiplexer to transfer data from the first input to the output of the multiplexer during the fourth clock cycle.

29. The apparatus of claim 26, wherein:
the means for activating the first memory block comprises:
means for activating one of a first set of memory locations of a memory device to transfer data to an input of a first pre-multiplexer; and
means for activating the first pre-multiplexer to transfer data to the first input of the multiplexer;
the means for activating the second memory block comprises:
means for activating one of a second set of memory locations of the memory device to transfer data to an input of a second pre-multiplexer; and
means for activating the second pre-multiplexer to transfer data to the second input of the multiplexer;
the means for activating the third memory block comprises:
means for activating one of a third set of memory locations of the memory device to transfer data to an input of a third pre-multiplexer; and
means for activating the third pre-multiplexer to transfer data to the third input of the multiplexer; and
the means for activating the fourth memory block comprises:
means for activating one of a fourth set of memory locations of the memory device to transfer data to an input of a fourth pre-multiplexer; and
means for activating the fourth pre-multiplexer to transfer data to the fourth input of the multiplexer.

30. The apparatus of claim 29, wherein the memory device comprises a first-in-first-out (FIFO) memory.
